(19) United States
(12) Patent Application Publication
(10) Pub. No.: US 2011/0209759 A1
(43) Pub. Date: Sep. 1, 2011

(54) ARCHITECTURE FOR HIGH EFFICIENCY POLYMER PHOTOVOLTAIC CELLS USING AN OPTICAL SPACER

(75) Inventors: Kwanghee LEE, Gwangju (KR); Alan J. Heeger, Santa Barbara, CA (US)

(73) Assignee: The Regents of the University of California, Oakland, CA (US)

(21) Appl. No.: 12/983,854

(22) Filed: Jan. 3, 2011

Related U.S. Application Data
(63) Continuation of application No. 11/347,111, filed on Feb. 2, 2006, now abandoned.
Application No. 11/347,111 is a continuation-in-part of application No. 11/326,130, filed on Jan. 4, 2006, now abandoned.
(60) Provisional application No. 60/663,398, filed on Mar. 17, 2005.
(60) Provisional application No. 60/663,398, filed on Mar. 17, 2005.

(51) Int. Cl. H01L 31/0232; H01L 51/46; H01L 31/18; B82Y 99/00

(52) U.S. Cl. 136/259; 136/263; 438/72; 977/753; 977/948; 257/E31.127

(57) ABSTRACT

High efficiency polymer photovoltaic cells have been fabricated using an optical spacer between the active layer and the electron-collecting electrode. Such cells exhibit approximately 50% enhancement in power conversion efficiency. The spacer layer increases the efficiency by modifying the spatial distribution of the light intensity inside the device, thereby creating more photogenerated charge carriers in the bulk heterojunction layer.

### CROSS-REFERENCE TO RELATED PATENT APPLICATIONS

This application is a continuation application of U.S. patent application Ser. No. 11/347,111, filed Feb. 2, 2006, which claimed the benefit under 35 USC 119(e) of U.S. Application Ser. No. 60/663,398, filed Mar. 17, 2005. U.S. patent application Ser. No. 11/347,111, filed Feb. 2, 2006 is also a continuation-in-part application of U.S. patent application Ser. No. 11/326,130, filed Jan. 4, 2006, which claimed the benefit under 35 USC 119(e) of U.S. Application Ser. No. 60/663,398, filed Mar. 17, 2005. All of the foregoing applications are hereby incorporated herein by reference in their entirety.

### BACKGROUND OF THE INVENTION

1. Field of the Invention

This invention relates to improved architecture for polymer-based photovoltaic cells and methods for the production of cells having the improved architecture.

2. Background Information

Photovoltaic cells having active layers based on organic polymers, in particular polymer-fullerene composites, are of interest as potential sources of renewable electrical energy. (See references 1-4 in the references listed at the end of the text of this application. References are identified throughout this application by the numbers provided in this list. All the references listed herein are incorporated by reference in their entirety.) Such cells offer the advantages implied for polymer-based electronics, including low cost fabrication in large sizes and low weight on flexible substrates. This technology enables efficient “plastic” solar cells which would have major positive impacts on the world's energy needs. Although encouraging progress has been made in recent years with 3-4% power conversion efficiencies reported under AM1.5 (AM=air mass) illumination (5,6), this efficiency is not sufficient to meet realistic specifications for commercialization. The need to improve the light-to-electricity conversion efficiency requires the implementation of new materials and the exploration of new device architectures.

Polymer-based photovoltaic cells may be described as thin film devices fabricated in the metal-insulator-metal (MIM) configuration sketched in FIG. 1A. Devices of the art have had the configuration shown in FIG. 1A1 as device 10. In this configuration, an absorbing and charge-separating bulk heterojunction layer 11, (or “active layer”) with thickness of approximately 100 nm is sandwiched between two charge-selective electrodes 12 and 14. These electrodes differ from one another in work function. The work function difference between the two electrodes provides a built-in potential that breaks the symmetry thereby providing a driving force for the photo-generated electrons and holes toward their respective electrodes with the higher work function electrode 12 collecting holes and the lower work function electrode 14 collecting electrons. As shown in FIG. 1A1, these devices of the art also include a substrate 15 upon which the MIM structure is constructed. Alternatively, the positions of the two electrodes relative to the support can be reversed. In the most common configurations of such devices, the substrate 15 and the electrode 12 are transparent and the electrode 14 is opaque and reflective such that the light which gives rise to the photoelectric effect enters the device through support 15 and electrode 12 and reflects back through the device off of electrode 14.

Because of optical interference between the incident light 17 and back-reflected light 18 (light is incident from the electrode 12 side), the optical electric field goes to zero at electrode 14 (7-9). Thus, as sketched in FIG. 1A3, in devices of the art a relatively large fraction of the active layer is in dead-zone 16 in which the photogeneration of carriers is significantly reduced. Moreover, this effect causes more electron-hole pairs to be produced near electrode 12, a distribution which is known to reduce the photovoltaic conversion efficiency (10,11). This ‘optical interference effect’ is especially important for thin film structures where layer thicknesses are comparable to the absorption depth and the wavelength of the incident light 17, as is the case for photovoltaic cells fabricated from semiconducting polymers.

In order to overcome these problems, one might simply increase the thickness of the active layer 11 to absorb more light. Because of the low mobility of the charge carriers in the polymer-based active layers, however, the increased internal resistance of thicker films will inevitably lead to a reduced fill factor.

### STATEMENT OF THE INVENTION

We have now found an alternative approach to solving this problem of internal reflection within polymer-based photovoltaic devices. This approach is to change the device architecture with the goal of spatially redistributing the light intensity inside the device by introducing an optical spacer 19 between the active layer 11 and the reflective electrode 14 as shown in device 20 sketched in FIGS. 1A2 and 1A4. Since spacer 19 is located within the light path and electrical circuit of device 20 it needs to be compatible with both the light and electrical flows. Thus, the prerequisites for an ideal optical spacer layer 19 include the following: First, the layer 19 should be constructed of a material which is a good acceptor and an electron transport material with a conduction band edge lower in energy than that of the highest occupied molecular orbital (HOMO) of the material making up the active layer; Second, the layer 19 should be constructed of a material having the energy of its conduction band edge above (or close to) the Fermi energy of the adjacent electron-collecting electrode; and Third, it should be transparent over a significant portion of the solar spectrum. In addition and preferably, the layer 19 should be of a thickness which, taking into consideration the material from which the layer is formed and that material's index of refraction, provides a redistribution of a significant portion of the internal reflection within the device. As shown in FIG. 1A4 this configuration can reduce or eliminate the dead zone 16 in active layer 11.

Thus, this invention, in one embodiment, provides an improved photovoltaic cell. This cell includes an organic polymer active layer having two sides. One side is bounded by a transparent first electrode through which light can be admitted to the active layer. The second side is adjacent to a light-reflective second electrode which is separated from the second side by an optical spacer layer.

The spacer layer is substantially transparent in the visible wavelengths. It increases the efficiency of the device by modifying the spatial distribution of the light intensity within the photoactive layer, thereby creating more photogenerated charge carriers in the active layer.

In preferred embodiments the spacer layer is constructed of a material that is a good acceptor and an electron transport material with a conduction band lower in energy than that of the highest occupied molecular orbital of the organic polymer making up the photoactive layer.

Also in preferred embodiments the spacer layer is further characterized as being constructed of a material having the energy of its conduction band edge above or close to the Fermi energy of the adjacent electron-collecting electrode.

Good results are attained when the spacer layer has an optical thickness equal to about a quarter of the wavelength of at least a portion of the incident light. The term “optical thickness” refers to the actual physical thickness of the layer multiplied by the index of refraction of the material from which the layer is formed.

Good results are attained when the spacer layer is constructed of a metal oxide, in particular an amorphous metal oxide and especially amorphous titanium oxide or zinc oxide. When the term “titanium oxide” is used as a material of construction for the layer 19 it is intended to refer not only to amorphous titanium dioxide but also, and generally preferably, to titanium suboxide. Titanium suboxide is a titanium oxide in which the titanium is less than completely oxidixed and which is referred to herein as TiOₓ with the understanding that “x” in this formula is generally less than 2, for example from about 1 to about 2.

It will be appreciated, however, that these materials, while preferred, are merely representative. Other materials meeting the optical and electrical selection criteria just recited may be used as well. These other materials can include conductive organic polymers meeting the criteria can be used. Other representative organic materials include InZnOxide and LiZnOxide for example.

In preferred embodiments the hole-collecting electrode is a bilayer electrode and the active layer comprises an organic polymer in admixture with a fullerene.

In another embodiment this invention provides an improved method of preparing an organic polymer-based photovoltaic cell comprising a transparent substrate, a transparent hole-collecting electrode on the support, an organic polymer-based active layer on the hole-collecting electrode. The improvement comprises casting a layer of a titanium oxide precursor solution onto the active layer and thereafter heating the cast layer of titanium oxide precursor to convert the precursor to titanium oxide to provide a spacer layer.

### DETAILED DESCRIPTION OF THE INVENTION

### Brief Description of the Drawings

This invention will be further described with reference to the accompanying drawings in which:

FIG. 1A1 is a schematic cross-sectional view of a photovoltaic cell device of the prior art;

FIG. 1A2 is a schematic cross-sectional view of a photovoltaic cell device of this invention with its added spacer layer;

FIG. 1A3 is a schematic view of a photovoltaic cell device of the prior art presenting the distribution of the squared optical electric field strength (E²) inside a representative device of the prior art which lacks an optical spacer. The dark region in the right hand portion of the active layer denotes the dead-zone as explained in the text;

FIG. 1A4 is a schematic view of a photovoltaic cell device of the invention illustrating the distribution of the squared optical electric field strength (E²) inside a representative device of the invention which includes an optical spacer;

FIG. 1B1 is a schematic illustration of a representative thin film photovoltaic cell of the present invention in which the device consists of a P3HT:PCBM active layer sandwiched between an Al electrode and a transparent ITO electrode coated with PEDOT:PSS. A TiOₓ optical spacer layer is inserted between the active layer and the Al electrode. A brief flow chart of the chemical steps involved in a representative preparation of a TiOₓ spacer layer is also included in this figure;

FIG. 1B2 illustrates the energy levels of the single components of the representative photovoltaic cell shown in FIG. 1B1, which show that this device exhibits excellent band matching for cascading charge transfer;

FIG. 2A is a tapping mode atomic force microscope image which shows the surface morphology of a representative TiOₓ spacer film;

FIG. 2B is a graph showing X-ray diffraction patterns of a representative relatively amorphous TiOₓ spacer layer formed at room temperature (bottom curve) and of TiO₂ powder that has been calcined at 500° C. (top curve) and exhibits a much more pronounced crystalline structure;

FIG. 2C is the absorption spectrum of a spin coated TiOₓ film which can serve as a representative spacer layer in the photovoltaic cells of this invention. This spectrum shows that the TiOₓ film is transparent in the visible range;

FIG. 3A is a graph in which the incident monochromatic photon to current collection efficiency (IPCE)] spectra are compared for the two representative devices with and without a TiOₓ optical spacer layer;

FIG. 3B is a pair of absorption spectra obtained from reflectance measurements in which the lower curve depicts the absolute value of the absorbance of the P3HT:PCBM active layer composite and the upper curve depicts the ratio of the intensity of reflectance observed with devices of this invention with their spacer layers divided by the intensity of reflection under the same conditions in devices of the prior art which do not include the spacer layer. The inset is a schematic description of the optical beam path in the samples used to determine the upper curve in FIG. 3B; and

FIG. 4A. is a pair of graphs showing the current density-voltage characteristics of representative polymer photovoltaic cells with and without a representative TiOₓ optical spacer illuminated with 25 mW/cm2 at 532 nm. The conventional device (upper curve) exhibits Voc=0.60 V, Jsc=8.41 mA/cm2, and FF=0.40 with ηe=8.1%, while the new device with the TiOₓ spacer layer (lower curve) exhibits Voc=0.62 V, Jsc=11.80 mA/cm2, and FF=0.45 with ηe=12.6%.

FIG. 4B is a pair of graphs showing the current density-voltage characteristics of representative polymer photovoltaic cells with and without a representative TiOₓ optical spacer illuminated under AM1.5 conditions with a calibrated solar simulator with radiaytion intensity of 90 mW/cm2. The conventional device (upper curve) exhibits Voc=0.56 V, Jsc=10.1 mA/cm2, and FF=0.55 with ηe=3.5%, while the new device with the TiOₓ spacer layer (lower curve) exhibits Voc=0.61 V, Jsc=11.1 mA/cm2, and FF=0.66 with ηe=5.0%.

FIG. 5. is a series of graphs showing the current density-voltage characteristics of representative polymer photovoltaic cells with and without representative zinc oxide optical spacers illuminated with 25 mW/cm2 at 532 nm. The conventional device (upper curve) exhibits Voc=0.58 V, Jsc=7.26 mA/cm2, and FF=0.41 with ηe=2.2%, while the new devices with the ZnO spacer layers (lower curves) exhibit Voc=0.62 V, Jsc=7.68, 7.89, 7.76 mA/cm2, and FF=0.45 with ηe=12.6%.

### DESCRIPTION OF PREFERRED EMBODIMENTS

This Description of Preferred Embodiments begins with a brief description of the materials and configurations of the photovoltaic cells which benefit from the spacers of this invention. This is followed by a more detailed examination of the spacer layers and its function.

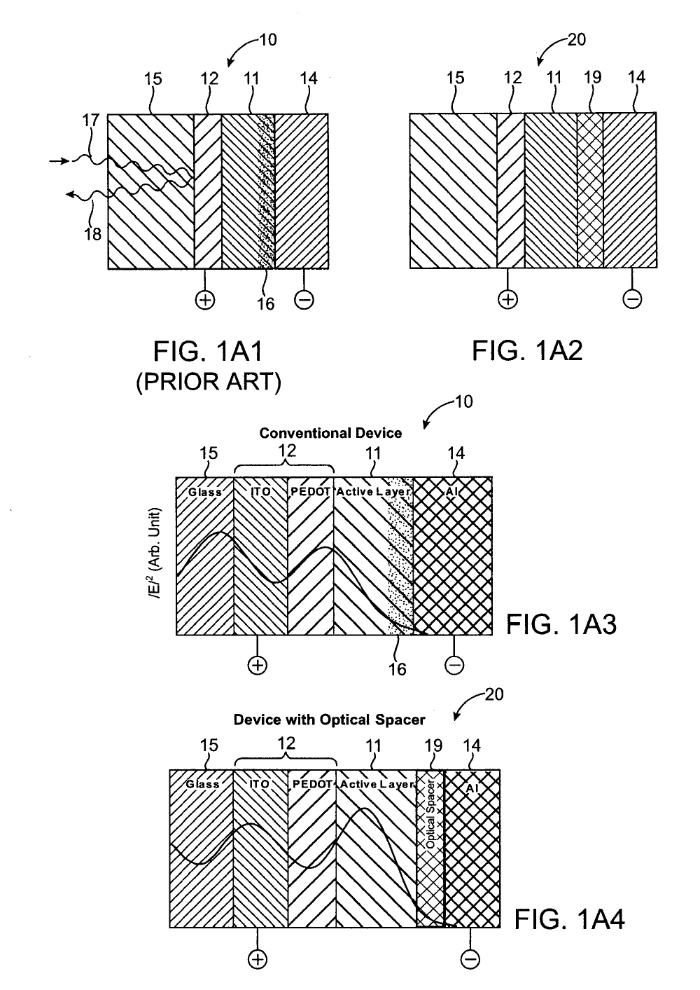

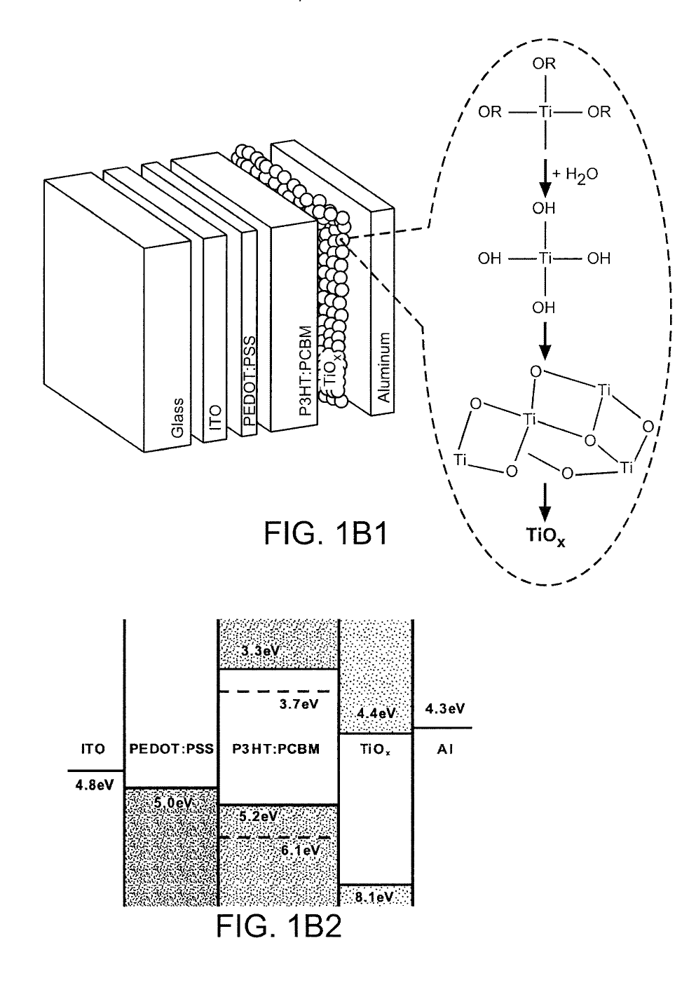

As shown in FIG. 1A2, the present photovoltaic cells to which the spacer is added include the following elements:
a substrate/support;
a hole-collecting electrode;
an active layer; and
an electron-collecting electrode. These elements will be described and then the spacer layer which improves these devices will be discussed.

The Substrate/Support

The substrate provides physical support for the photovoltaic device. In most configurations, light enters the cell through the substrate such that the substrate is transparent, that it provides at least 70% and preferably at least 80% average transmission over the visible wavelengths of about 400 nm to about 750 nm, and preferably significant transmission in the infrared and ultraviolet regions of the solar spectrum, as well.

Examples of suitable transparent substrates include rigid solid materials such as glass or quartz and rigid and flexible plastic materials such as polycarbonates and polyesters for example poly(ethylene terephthalate) “PET”.

The Hole-Collecting Electrode

This electrode is very commonly on or adjacent to the substrate and is in the transmission path of light into the cell. Thus, it should be “transparent” as defined herein, as well. This electrode is a high work function electrode.

The high work function electrode is typically a transparent conductive metal-metal oxide or sulfide material such as indium-tin oxide (ITO) with resistivity of 20 ohm/square or less and transmission of 89% or greater @ 550 nm. Other materials are available such as thin, transparent layers of gold or silver. A “high work function” in this context is generally considered to be a work function of about 4.5 eV or greater. This electrode is commonly deposited on the solid support by thermal vapor deposition, electron beam evaporation, RF or Magnetron sputtering, chemical deposition or the like. These same processes can be used to deposit the low work-function electrode as well. The principal requirement of the high work function electrode is the combination of a suitable work function, low resistivity and high transparency.

In preferred embodiments, the hole-collecting electrode is accompanied by a hole-transport layer located between the high work function electrode and the active layer. This provides a “bilayer electrode”.

When a hole-transport layer is present to provide a bilayer electrode, it is typically 20 to 30 nm thick and is cast from solution onto the electrode. Examples of materials used in the transport layer include semiconducting organic polymers such as PEDOT:PSS cast from a polar (aqueous) solution or the precursor of poly(BTPD-Si—PFCB) [S. Liu, X. Z. Jiang, H. Ma, M. S. Liu, A. K.-Y. jen, Macro., 2000, 33, 3514; X. Gong, D. Moses, A. J. Heeger, S. Liu and A. K.-Y. Jen, Appl. Phys. Lett., 2003, 83, 183]. PEDOT:PSS is preferred. On the other hand, by using poly(BTPD-Si—PFCB) as hole injection layer, many processing issues existing in PLEDs, brought about by the use of PEDOT:PSS, such as the undesirable etching of active polymer, undesirable etching of ITO electrodes, and the formation of micro-shorts can be avoided [G. Greczynski, Th. Kugler and W. R. Salaneck, Thin Solid Films, 1999, 354, 129; M. P. de Jong, L. J. van Ijzendoorn, M. J. A. de Voigt, Appl. Phys. Lett. 2000, 77, 2255].

The Active Layer

The active layer is made of two components—a conjugated polymer which serves as an electron donor and a second component which serves as an electron acceptor. The second component can be a second conjugated organic polymer but better results are achieved if a fullerene is used.

It will be appreciated that the organic active layer defined as “a polymer” or as “conjugated” can also contain small organic molecules as described by P. Peumans, S. Uchida and S. R. Forrest, NATURE, 2003, 425, 158. (Incorporated by reference.)

Conjugated polymers include polyphenylenes, polyvinylenes, polyanilines, polythiophenes and the like. We have had our best results with poly(3-hexylthiophene), “P3HT”, as conjugated polymer.

By using fullerenes, particularly buckminsterfullerene “C₆₀”, as electron acceptors (U.S. Pat. No. 5,454,880), the charge carrier recombination otherwise typical in the photoactive layer may be largely avoided, which leads to a significant increase in efficiency.

Fullerenes and especially fullerene derivatives such as PCBM [6,6]-phenyl-C₆₁-buteric acid methyl ester are thus preferred. These active layers can be laid down using solution processes such as spin-casting and the like.

The Electron-Collecting Electrode

This electrode is a reflective low work function electrode, most commonly a metal and particularly an aluminum electrode. This electrode can be laid down using vapor deposition methods.

The Spacer Layer

The spacer layer is made from organic or inorganic materials meeting the electrical and optical criterion set forth in paragraphs 0007 through 0012 above. Titanium oxide (TiOₓ) and zinc oxide give good results.

Titanium dioxide (TiO₂) is a promising candidate as an electron acceptor and transport material as confirmed by its use in dye-sensitized Gräzel cells (12,13), hybrid polymer/TiO₂ cells (14-16), and multilayer Cu-phthalocyanine/dye/TiO₂ cells (9,17). Typically, however, crystalline TiO₂ is used, either in the anatase phase or the rutile phase, both of which require treatment at temperatures (T>450° C.) that are inconsistent with the device architecture shown in FIG. 1B. The polymeric photoactive layers such as those made of polymer/C60 composite cannot survive such high temperatures. We have used a solution-based sol-gel process to fabricate a titanium oxide (TiOₓ) layer on top of the polymer-fullerene active layer (FIG. 1B). By introducing the TiOₓ optical spacer, we demonstrate polymer photovoltaic cells with power conversion efficiencies that are increased by approximately 50% compared to those obtained without the optical spacer.

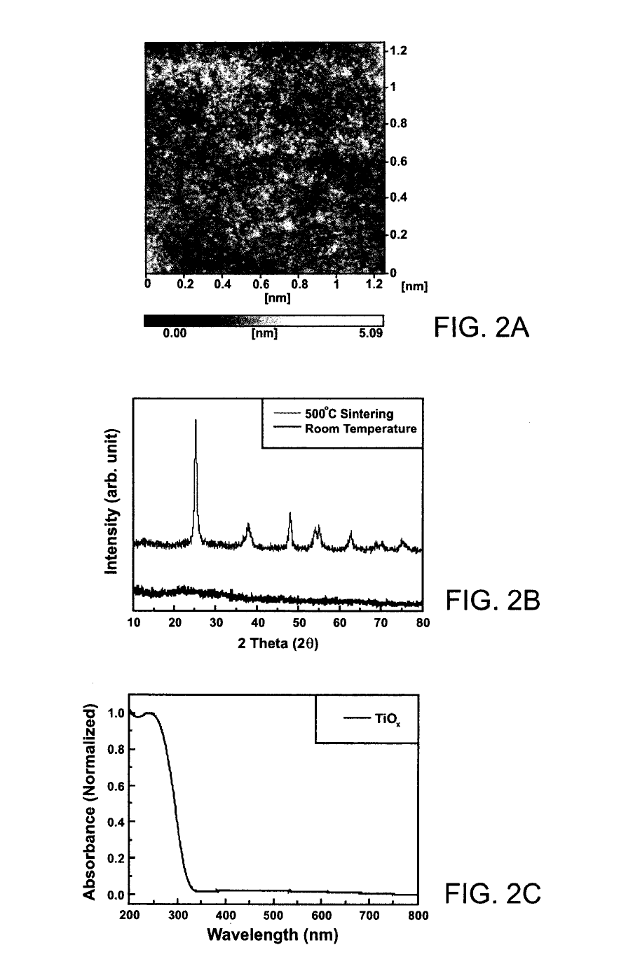

Dense TiOₓ films were prepared using a TiOₓ precursor solution, as described in detail elsewhere (18). The precursor solution was spin-cast in air on top of the polymer-fullerene composite layer. The sample was then heated under vacuum at 90° C. for 10 minutes during which time the precursor converts to the TiOₓ layer via hydrolysis. As shown in FIG. 2A, the resulting TiOₓ films are transparent and smooth with surface features less than a few nm.

The spacer layer can be from about 30 nm to about 1000 nm in physical thickness, especially from about 75 nm to about 750 nm. Ideally, the layer should present a smooth continuous layer with an “optical thickness” on the general order of ¼ the wavelength of at least a portion of the light being directed onto the cell. As noted previously, “optical thickness” is the product of the physical thickness and the index of refraction. Indeces of refraction for the materials from which the spacer layer is prepared run from a high of about 2.75 for various inorganic materials down to about 1.50 for organic spacer layer materials. The wavelengths of “light” should be considered to include not only the visible spectrum (about 400 nm to about 750 nm) but also the infrared (750 nm to 2500 nm) and ultraviolet (100 nm to 400 nm) portions of the solar spectrum. These considerations lead to preferred physical thicknesses for the spacer layer of from about 80-500 nm, more preferably 90-400 nm and for example 100 nm to about 200 nm.

Scanning Electron Microscope (SEM) and separate Photon Correlation (Light Scattering) Spectroscopy measurements confirm that the average size of the TiOₓ particles in the films is about 6 nm. However, since the layer was treated at temperatures below 100° C., the film is amorphous as confirmed by the X-ray diffraction (XRD) analysis (FIG. 2B). The typical XRD peaks of the anatase crystalline form appear only after sintering the spin-cast films at 500° C. for 2 hours. Analysis by X-ray Photoelectron Spectroscopy (XPS) reveals the oxygen deficiency in the thin film samples with Ti:O ratio in the range from 42.13%-56.38%; i.e. significantly below that of stoichiometric TiO₂; hence TiOₓ. In this formula, x is less than 2 such that the material is a “suboxide” usually x is from 1 to 1.96, preferably 1.1 to 1.9 and especially 1.2 to 1.9. These values also represent from 50% to 98% full oxidation, preferably 55% to 95% and especially 60% to 95% full oxidation.

While any compatible processing method may be used to apply the TiOₓ layers, solvent processing is preferred. In solvent processing, a layer of a solution or suspension (such as a colloidal suspension) of one or more TiOₓ precursors is applied. Solvent is removed, most commonly by evaporation to yield a continuous thin layer of TiOₓ or a TiOₓ precursor which upon further processing such as mild heating or the like is converted, it is believed by hydrolysis, to the TiOₓ layer. The precursor converts to TiOₓ by hydrolysis and condensation processes as follows:

Ti(OR)₄+4H₂O−>TiOₓ+YROH.

The solution of TiOₓ precursor is commonly a titanium alkoxide such as titanium(IV) butoxide, titanium(IV) chloride, titanium(IV) ethoxide, titanium(IV) methoxide, titanium(IV) propoxide. Such materials are commonly available and soluble in lower alkanols such as 1-4 carbon alkanols which are liquids which are generally compatible with and nondestructive to other organic polymer layers commonly found in microelectronic devices. Alkoxyalkanols such as methoxy-ethanol and the like can be used as well. Other titanium sources such as Ti(SO₄)₂, and so on can be used. The solvent selected should not react with the TiOₓ precursor. This suggests that care should be used if aqueous solvents or mixed aqueous/organic solvents are desired as the water component could cause premature reaction such as hydrolysis of the TiOₓ precursor. Another factor to be considered in selecting a titanium source/solvent combination is the ability of the combination to wet the substrate upon which the solution is being spread. The lower alkanol-based solutions/suspensions set forth above have given good wetting with organic layers.

Titanium concentration in the solution/suspension can vary from as low as 0.01% by weight to as much as 10% by weight or greater. While this has not been optimized, concentrations of from about 0.5 to 5% by weight have given good results.

The TiOₓ precursor solution/suspension is spread using conventional methods. Spin casting has given good results.

The layer of precursor solution is formed by heating the solution of starting materials for a time and at a temperature suitable to react the starting material but not so high as to cause conversion of the starting material to a full stiochiometric oxide. Temperatures of from about 50 degrees centigrade to about 150 degrees centigrade and times of from about 0.1 hour (at the higher temperature) to about 12 hours (at the lower temperatures) can be employed. Preferred temperature and time ranges are from about 80 degrees to about 120 degrees for from 1 to 4 hours, again with the higher temperatures using the shorter times and the lower temperatures needing the longer times.

It is a good idea to exclude oxygen during the casting and heating of the solution of the TiOₓ precursors. This prevents premature conversion of the precursor to TiOₓ or the conversion of the TiOₓ precursor to the full TiO₂ oxide. This can be accomplished by carrying out the casting and solution preparation under vacuum or in an inert (non oxygen) atmosphere such as an argon or nitrogen atmosphere. Additional information about the handling and use of titanium based solutions and suspensions can be found in the following references which are incorporated by reference:
1. T. Sugimooto, et al., J. Colloid Interface Sci. 259, 43-52 (2003).
2. W. Shangguan, et al., Sol. Energy Mater. Sol. Cells 80, 433-441 (2003).
3. S. Lee, et al., Chem. Mater. 16, 4292-4295 (2004).
4. Z. Zhong, et al., Chem. Mater. 17, 6814-6818 (2005).

In spite of the amorphous nature of the TiOₓ layer, the physical properties are excellent. The absorption spectrum of the film shows a well-defined absorption edge at Eg≈3.7 eV. Although this value is somewhat higher than that of the bulk anatase samples (Eg≈3.2 eV), the value is consistent with the calculation of the modified particle in a sphere model for the size dependence of semiconductor band gaps (19). Using optical absorption and Cyclic Voltammetry (CV) data, the energies of the bottom of the conduction band (LUMO) and the top of the valence band (HOMO) of the TiOₓ material were determined; see FIG. 1B. This energy level diagram demonstrates that the TiOₓ layer satisfies the electronic structure requirements of the optical spacer.

Utilizing this TiOₓ layer as the optical spacer, we fabricated donor/acceptor composite photovoltaic cells using the phase separated “bulk heterojunction” material comprising poly(3-hexylthiophene) (P3HT) as the electron donor and the fullerene derivative, [6,6]-phenyl-C₆₁ butyric acid methyl ester (PCBM) as the acceptor. The device structure is shown in FIG. 1B.

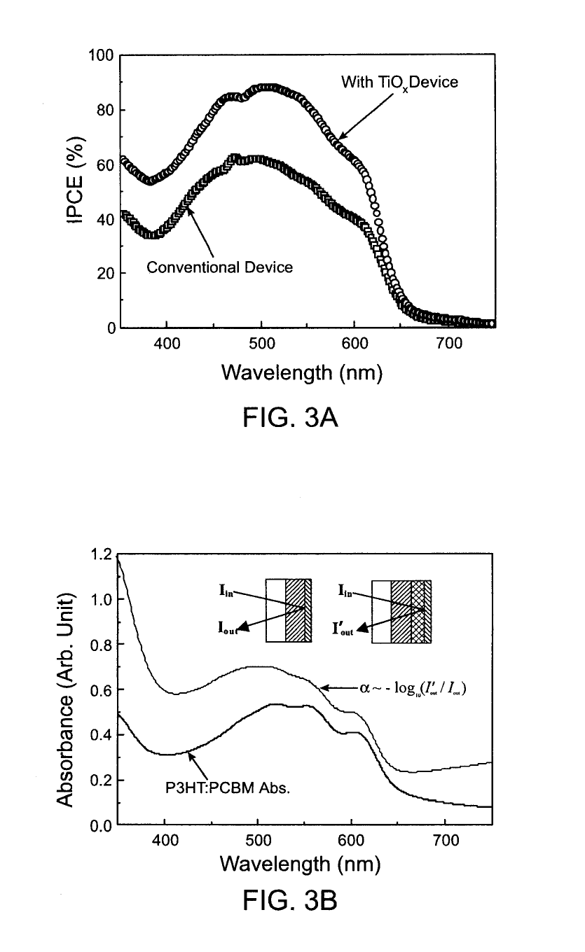

FIG. 3A compares the incident photon to current collection efficiency spectrum (IPCE) of devices fabricated with and without the TiOₓ optical spacer. The IPCE is defined in terms of the number of photo-generated charge carriers contributing to the photocurrent per incident photon. The conventional device (without the TiOₓ layer) shows the typical spectral response of the P3HT:PCBM composites with a maximum IPCE of ˜60% at 500 nm, consistent with previous studies (3-6). For the device with the TiOₓ optical spacer, the results demonstrate substantial enhancement in the IPCE efficiency over the entire excitation spectral range; the maximum reaches almost 90% at 500 nm, corresponding to a 50% increase in IPCE.

We attribute this enhancement to the TiOₓ optical spacer; the increased photo-generation of charge carriers results from the spatial redistribution of the light intensity. In order to further clarify the role of the TiOₓ layer, we measured the reflectance spectrum from a “device” with glass/P3HT:PCBM/TiOₓ/Al geometry using a glass/P3HT:PCBM/Al “device” as the reference (the P3HT:PCBM composite film thickness was about 100 nm in both). Note that the ITO/PEDOT layers were omitted to avoid any complication arising from the conducting layers. Since the two “devices” are identical except for TiOₓ optical spacer layer, comparison of the reflectance yields information on the additional absorption in the P3HT:PCBM composite film as a result of the spatial redistribution of the light intensity by the TiOₓ layer (20)

Δα(ω)≈−(½d)1n[I′ₒᵤₜ(ω)/Iₒᵤₜ(ω)] (1)

where I′ₒᵤₜ(ω) is the intensity of the reflected light from the device with the optical spacer and Iₒᵤₜ(ω) is the intensity of the reflected light from an identical device without the optical spacer.

The data demonstrate a clear increase in absorption over the entire spectrum. Moreover, since the spectral features of the P3HT:PCBM absorption are evident in both spectra, the increased absorption arises from a better match of the spatial distribution of the light intensity to the position of the P3HT:PCBM composite film. We conclude that the higher absorption is caused by the TiOₓ layer as an optical spacer as sketched in FIG. 1A. As a result, the TiOₓ optical spacer increases the number of carriers per incident photon collected at the electrodes.

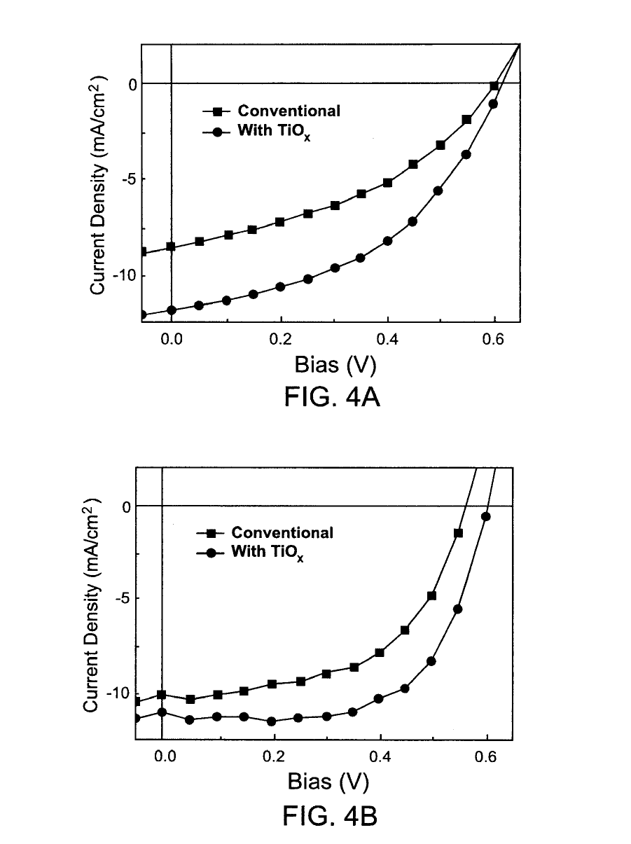

As shown in FIG. 4A, the enhancement in the device efficiency that results from the optical spacer can be directly observed in the current density vs voltage (J-V) characteristics under monochromatic illumination with 25 mW/cm2 at 532 nm. The conventional device (without the TiOₓ layer) shows typical photovoltaic response with device performance comparable to that reported in previous studies; the short circuit current (Isc) is Jsc=8.4 mA/cm2, the open circuit voltage (Voc) is Voc=0.6 V, and the fill factor (FF) is FF=0.40. These values correspond to a power conversion efficiency (ηp) of ηe=8.1% (under 25 mW/cm2 monochromatic illumination at 532 nm). For the device with the TiOₓ layer, the results demonstrate substantially improved device performance; Isc increases to Jsc=11.8 mA/cm2, the FF increases slightly to FF=0.45, while Voc remains at 0.6 V. The corresponding power conversion efficiency is ηe=12.6%, which corresponds to ˜50% increase in the device efficiency, consistent with the IPCE measurements.

Under AM1.5 illumination from a calibrated solar simulator with irradiation intensity of 100 mW/cm2, we observed a consistent enhancement in the device efficiency using the TiOₓ optical spacer. While the conventional device (without the TiOₓ layer) again shows typical photovoltaic responses with a device efficiency of typically 3%, devices fabricated identically, but with the TiOₓ layer, demonstrate substantially improved device performance with efficiency of 4%, which corresponds to ˜33% increase.

The additional data obtained under AM1.5 illumination from a calibrated solar simulator with irradiation intensity of 90 mW/cm² are shown in FIG. 4B. The device without the TiOₓ layer again shows typical photovoltaic response with device performance comparable to that reported in previous studies; J_{sc}=10.1 mA/cm², V_{oc}=0.56 V, FF=0.55 and ηₑ=3.5%. For the device with the TiOₓ layer, the results demonstrate substantially improved device performance; J_{sc}=11.1 mA/cm², V_{oc}=0.61 V, FF=0.66. The corresponding power conversion efficiency is ηₑ=5.0%, which corresponds to ˜40% increase in the device efficiency. Postproduction annealing at 150° C. improves the morphology and crystallinity of the bulk heterojunction layer with a corresponding increase in solar conversion efficiency to 5% (7). Thus, we anticipate that by using the optical spacer architecture described here, one should be able to improve the performance to efficiencies in excess of 7%.

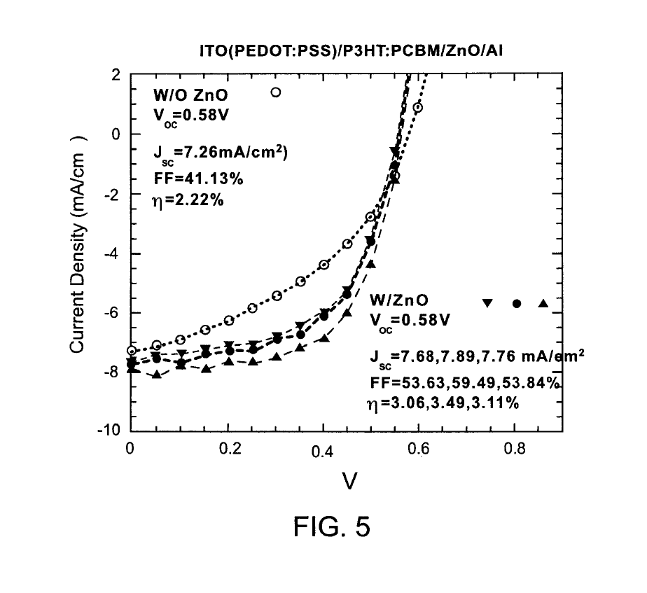

The results presented in detail in this document utilized TiOₓ as the material for the optical spacer layer. Other inorganic spacer materials meeting the criteria set forth herein can be used. Examples of such materials include amorphous silicon oxide, SiOₓ, where x is similar to x in TiOₓ and ZnO. As shown in FIG. 5 we have also successfully demonstrated the use of ZnO (in the form of nanoparticles cast from aqueous solution) as the material for the optical spacer. A suitable ZnO nanoparticle suspension can be formed using a sol-gel synthesis procedure for producing zinc oxide (ZnO) is as follows; zinc acetate dihydrate [Zn(CH₃CO₂)₂.2H₂O, Aldrich, 98+%, 10 mg] was dehydrated using about one hour in vacuum 120° C. and mixed with 2-methoxyethanol (CH₃OCH₂CH₂OH, Aldrich, 99.9+%, 50 mL) and ethanolamine (H₂NCH₂CH₂OH, Aldrich, 99+%, 5 mL) in a three-necked flask each connected with a condenser, thermometer, and argon gas inlet/outlet. Then, the mixed solution was heated to 80° C. for 2 hours in a silicon oil bath under magnetic stirring, followed by heating to 120° C. for 1 hour. The two-step heating (80° C. and 120° C.) is then repeated. The typical ZnO precursor solution was prepared in isopropyl alcohol. The thin film coating technology using this ZnO precursor solution is more or less similar to that of sol-gel processed TiOₓ. The energy of the bottom of the conduction band of ZnO is also well matched to the LUMO of C60 (PCBM). FIG. 5 shows a series of graphs showing the current density-voltage characteristics of representative polymer photovoltaic cells with and without representative zinc oxide optical spacers illuminated with 25 mW/cm2 at 532 nm The conventional device (upper curve) exhibits Voc=0.58 V, Jsc=7.26 mA/cm2, and FF=0.41 with ηe=2.22%, while the new devices with the ZnO spacer layers (lower curves) exhibit Voc=0.58 V, Jsc=7.68, 7.89, 7.76 mA/cm2, and FF=53.63, 59.49 and 53.84% with ηe=3.06, 3.49, and 3.11%.

Organic spacer layers can be used as well. Such organic spacer materials can be dissolved in water and/or methanol for coating this material on top of the organic layer without damage. Thus, candidates for organic spacer materials are recently-developed water soluble polymers, ionic polymers such as anion-PF, cation-PF, PFON⁺(CH₃)₃IPBD, PVK-SO₃Li, t-Bu-PBD-SO₃Na, and the like.

The semiconducting polymer used in the active layers in these studies, P3HT, has a relatively large energy gap (approx. 2 eV). As a result, almost half of the energy in the solar spectrum is at wavelengths in the near infra-red at wavelengths too long to be absorbed. We anticipate that utilizing both a semiconducting polymer with energy gap well matched to the solar spectrum and the optical spacer concept described here will result in polymer solar cells with approximately 10% efficiency for conversion of sunlight to electricity. Low cost plastic solar cells with power conversion efficiencies approaching 10% could have major impact on the energy needs of our society.

While the scope of the invention is defined solely by the claims herein, the following examples explain the manufacture and testing of devices of the invention in more detail.

### Example 1

The sol-gel procedure for producing TiOₓ is as follows; titanium isopropoxide (Ti[OCH(CH₃)₂]₄, Aldrich, 97%, 10 mL) was prepared as a precursor, and mixed with 2-methoxyethanol (CH₃OCH₂CH₂OH, Aldrich, 99.9+%, 150 mL) and ethanolamine (H₂NCH₂CH₂OH, Aldrich, 99.5+%, 5 mL) in a three-necked flask equipped with a condenser, thermometer, and argon gas inlet/outlet. Then, the mixed solution was heated to 80° C. for 2 hours in silicon oil bath under magnetic stiffing, followed by heating to 120° C. for 1 hour. The two-step heating (80° C. and 120° C.) was then repeated. The typical TiOₓ precursor solution was prepared in isopropyl alcohol.

For the preparation of the polymer-fullerene composite solar cells in the structure shown in FIGS. 1A4 and 1B1 and 1B2, we used regioregular poly(3-hexylthiopene) (P3HT) as the electron donor, and the fullerene derivative, [6,6]-phenyl-C61 butyric acid methyl ester (PCBM) as the electron acceptor. The P3HT:PCBM composite weight ratio was 1:1. After spin casting poly(3,4-ethylenedioxylenethiophene)-polystyrene sulfonic acid (PEDOT:PSS) on TTO glass substrates, with subsequent drying for a period of 30 minutes at 120° C., a thin layer of P3HT:PCBM was spin-cast onto the PEDOT:PSS with a thickness of 100 nm. Then, the TiOₓ layer (30 nm) was spin-cast onto the P3HT:PCBM composite from the precursor solution followed by annealing at 90° C. for 10 minutes. Finally, the Al electrode was thermally evaporated onto the TiOₓ layer in vacuum at pressures below 10-6 Torr.

In a second, more optimized device fabrication, the sol-gel procedure for producing titanium oxide (TiOₓ) is as follows; titanium isopropoxide (Ti[OCH(CH₃)₂]₄, Aldrich, 99.999%, 10 mL) was prepared as a precursor and mixed with 2-methoxyethanol (CH₃OCH₂CH₂OH, Aldrich, 99.9+%, 50 mL) and ethanolamine (H₂NCH₂CH₂OH, Aldrich, 99+%, 5 mL) in a three-necked flask equipped connected with a condenser, thermometer, and argon gas inlet/outlet. Then, the mixed solution was heated to 80° C. for 2 hours in silicon oil bath under magnetic stirring, followed by heating to 120° C. for 1 hour. The two-step heating (80 and 120° C.) was then repeated. The typical TiOₓ precursor solution was prepared in isopropyl alcohol.

The bulk heterojunction solar cells using poly(3-hexylthiophene) (P3HT) as the electron donor and [6,6]-phenyl-C₆₁butyric acid methyl ester (PCBM) as the acceptor were fabricated in the structure shown in FIG. 1B. The details of the device fabrication (solvent, P3HT/PCBM ratio and concentrations) can have direct impact on the device performance.

Solvent: For achieving optimum performance, we used chlorobenzene as the solvent. P3HT/PCBM Ratio and Concentration: The best device performance is achieved when the mixed solution had a P3HT/PCBM ratio of 1.0:0.8; i.e. with a concentration of 1 wt % P3HT(1 wt %) plus PCBM(0.8 wt %) in chlorobenzene.

Device Fabrication: Polymer solar cells were prepared according to the following procedure: An ITO-coated glass substrate was first cleaned with detergent, then ultrasonicated in acetone and isopropyl, and subsequently dried in an oven overnight. Highly conducting poly(3,4-ethylenedioxylenethiophene)-polystyrene sulfonic acid (PEDOT:PSS, Baytron P) was spin-cast (5000 rpm) with thickness ˜40 nm from aqueous solution (after passing a 0.45 μm filter). The substrate was dried for 10 minutes at 140° C. in air, and then moved into a glove box for spin-casting the photoactive layer. The chlorobenzene solution comprised of P3HT (1 wt %) plus PCBM (0.8 wt %) was then spin-cast at 700 rpm on top of the PEDOT layer. Then the TiOₓ precursor solution was spin-cast in air on top of the polymer-fullerene composite layer. Subsequently, during one hour in air at room temperature, the precursor converts to TiOₓ by hydrolysis. The sample was then heated at 150° C. for 10 minutes inside a glove box filled with nitrogen. Subsequently the device was pumped down in vacuum (<10-7 torr), and a ˜100 nm Al electrode was deposited on top.

Calibration and Measurement: For calibration of our solar simulator, we first carefully minimized the mismatch of the spectrum (the simulating spectrum) obtained from the Xenon lamp (150 W Oriel) and the solar spectrum using an AM1.5 filter. We then calibrated the light intensity using carefully calibrated silicon photovoltaic (PV) solar cells. In detail, we used several calibrated silicon solar cells and silicon photodiodes and measured both the short-circuit current and the open-circuit voltage. In order to confirm the accuracy of the solar simulator at Univ. of California at Santa Barbara (UCSB), we carried out a cross-calibration between the solar simulator at UCSB and the solar simulator at Konarka Technologies (Lowell, Mass.). The accuracy of the solar simulator at Konarka is based on standard cells traced to the National Renewable Energy Laboratory (NREL). Measurements were done with the solar cells inside the glove box by using a high quality optical fiber to guide the light from the solar simulator (outside the glove box). Current density-voltage curves were measured with a Keithley 236 source measurement unit.

### REFERENCES

1. N. S. Sariciftci, L. Smilowitz, A. J. Heeger, F. Wudl, Science 258, 1474 (1992).
2. N. S. Sariciftci and A. J. Heeger, U.S. Pat. No. 5,454,880
3. G. Yu, J. Gao, J. C. Hemmelen, F. Wudl, A. J. Heeger, Science 270, 1789 (1995).
4. C. J. Brabec, N. S. Sariciftci, J. C. Hummelen, Adv. Funct. Mater. 11, 15 (2001).
5. C. J. Brabec, Sol. Energy Mater. Sol. Cells 83, 273 (2004).
6. S. E. Shaheen, C. J. Brabec, N. S. Sariciftci, F. Padinger, T. Fromherz, J. C. Hummelen, Appl. Phys. Lett. 78, 841 (2001).
7. F. Padinger, R. Rittberger, and N. S. Sariciftci, Adv. Funct. Mater. 13, 85 (2003).
8. L. A. A. Pettersson, L. S. Roman, O. Ingands, J. Appl. Phys. 86, 487 (1999).
9. T. Stübinger and W. Brütting, J. Appl. Phys. 90, 3632 (2001).
10. H. Hänsel, H. Zettl, G. Krausch, R. Kisselev, M. Thelakkat, and H-W. Schmidt, Adv. Mater 15, 2056 (2003).
11. H. J. Snaith, N. C. Greenham, and R. H. Friend, Adv. Mater 16, 1640 (2004).
12. C. Melzer, E. J. Koop, V. D. Mihaletchi, and P. W. M. Blom, Adv. Func. Mater. 14, 865 (2004).
13. B. O'Regan, M. Gräzel, Nature 353, 737 (1991).
14. U. Bach, D. Lupo, P. Comte, J. E. Moser, F. Weissortel, J. Salbeck, H. Spreitzel, M. Gräzel, Nature 395, 583 (1998).
15. C. Arango, L. R. Johnson, V. N. Bliznyuk, Z. Schlesinger, Sue A. Carter, H-H., Horhold, Adv. Mater. 12, 1689 (2000).
16. J. Breeze, Z. Schlesinger, S. A. Carter, P. J. Brock, Phys. Rev. B 64, 125205 (2001).
17. P. A. van Hal, M. M. Wienk, J. M. Kroon, W. J. H. Verhees, L. H. Slooff, W. J. H. Van Gennip, P. Jonkheijm, R. A. Janssen, Adv. Mater. 15, 118 (2003).
18. M. Thelakkat, C. Schmitz, and H.-W. Schmidt, Adv. Mater. 14, 577 (2002).
19. H. H. Lee, S. H. Kim, J. Y. Kim, K. Lee (unpublished).
20. Y. I. Kim, S. W. Keller, J. S. Krueger, E. H. Yonemoto, G. B. Saupe, T. E. Malouk, J. Phys. Chem. B 101, 2491 (1997).
21. K. Lee, Y. Chang, J. Y. Kim, Thin Solid Films 423, 131 (2003).

What is claimed is:

1. In a photovoltaic cell which includes an organic polymer-based photoactive layer having two sides, one side bounded by a transparent first electrode through which light can be admitted to the photoactive layer and the second side adjacent to a light-reflective second electrode, the improvement comprising an optical spacer layer separating the photoactive layer from the reflective second electrode.

2. The photovoltaic cell of claim 1 wherein the spacer layer is substantially transparent in the visible wavelengths.

3. The photovoltaic cell of claim 2 wherein the spacer layer increases the efficiency of the device by modifying the spatial distribution of the light intensity within the photoactive layer, thereby creating more photogenerated charge carriers in the active layer.

4. The photovoltaic cell of claim 3 wherein the reflective second electrode is an electron-collecting electrode and wherein the transparent electrode is a hole-collecting electrode.

5. The photovoltaic cell of claim 4 wherein the spacer layer is constructed of a material that is a good acceptor and an electron transport material with a conduction band lower in energy than that of the highest occupied molecular orbital of the organic polymer making up the photoactive layer.

6. The photovoltaic cell of claim 5 wherein the spacer layer is constructed of a material having a material having the energy of its conduction band edge above or close to the Fermi energy of the adjacent electron-collecting electrode.

7. The photovoltaic cell of claim 2 wherein the spacer layer has a thickness about a quarter of the wavelength of the incident light.

8. The photovoltaic cell of claim 6 wherein the spacer layer is constructed of a metal oxide.

9. The photovoltaic cell of claim 6 wherein the spacer layer is constructed of an amorphous metal oxide.

10. The photovoltaic cell of claim 9 wherein the spacer layer comprises titanium oxide or zinc oxide.

11. The photovoltaic cell of claim 6 wherein the spacer layer comprises an organic polymer.

12. The photovoltaic cell of claim 1 wherein the hole-collecting electrode is a bilayer electrode.

13. The photovoltaic cell of claim 1 wherein the active layer comprises an organic polymer in admixture with fullerene.

14. A photovoltaic cell comprising a transparent substrate, an ITO-.PEDOT:PSS bilayer hole-collecting electrode on the substrate, an organic polymer-based active layer comprising P3HT:PCBM on the hole-collecting electrode, an amorphous titanium oxide spacer layer on the active layer and a reflective metal electron-collecting electrode on the spacer layer.

15. In a method of preparing an organic polymer-based photovoltaic cell comprising a transparent substrate, a transparent hole-collecting electrode on the support, an organic polymer-based active layer on the hole-collecting electrode, the improvement comprising casting a layer of a titanium oxide precursor solution onto the active layer.

16. The method of claim 14 additionally comprising the step of heating the cast layer of titanium oxide precursor to convert the precursor to titanium oxide.
